(19) United States
(12) Patent Application Publication
(10) Pub. No.: US 2026/0079216 A1
(43) Pub. Date: Mar. 19, 2026

(54) BATTERY PACK TEST CONNECTOR

(71) Applicant: FasTest, Inc., Roseville, MN (US)

(72) Inventors: Robert Danielson, Roseville, MN (US); Jake Chandler, Roseville, MN (US); Ryan Kennedy, Roseville, MN (US); Ethan Nelson, Roseville, MN (US)

(21) Appl. No.: 19/312,712

(22) Filed: Aug. 28, 2025

Related U.S. Application Data
(60) Provisional application No. 63/694,615, filed on Sep. 13, 2024.

(51) Int. Cl. G01R 31/68; G01M 3/26; H01M 10/42

(52) U.S. Cl. CPC G01R 31/68; G01M 3/26; H01M 10/4228; H01M 10/4285

(57) ABSTRACT

A battery pack test connector that is configured for testing battery packs by connecting to a terminal on the battery pack to conduct the testing. The battery pack test connector can be configured to perform electrical testing, vacuum/pressure leak testing, or both electrical testing and vacuum/pressure leak testing. The ability to perform both electrical testing and leak testing using the same, single test connector eliminates the need for separate test connectors, one for electrical testing and one for vacuum/pressure leak testing. The test connector may also include a removable and replaceable cartridge that includes electrical contacts, a vacuum/pressure leak test passageway, and a mechanical seal for conducting leak testing. The cartridge allows replacement of worn parts without replacing the entire test connector.

### PRIORITY

This application claims the benefit of priority to U.S. Provisional Application No. 63/694615 filed on Sep. 13, 2024, the entire contents of which are incorporated herein by reference.

### FIELD

The technology described herein is directed to connectors used to test battery packs including, but not limited to, battery packs used for and on electric vehicles.

### BACKGROUND

Electric vehicle (EV) manufacturers and their battery pack suppliers test their battery packs for both electrical capabilities as well as ensuring they are leak free. To test the electrical connections, the battery terminals are connected to and voltage, amperage and conductive tests are then conducted. The same terminals are also connected to, sealed, and pressure or vacuum tests then conducted. The electrical tests are conducted using a first test connector while the pressure/vacuum tests are conducted using a second test connector. This increases the number of connectors that must be used to conduct the tests.

In addition, the connectors used for the electrical tests are discarded once the electrical terminals thereof wear out. With the number of cycles required for mass production of battery packs, the electrical connectors are an expensive wear item for the EV manufacturers and their battery pack suppliers.

### SUMMARY

A battery pack test connector is described that is configured for testing battery packs. The battery packs can be battery packs used in electrically powered vehicles including but not limited to, automobiles or cars, trucks, motorcycles, ATVs and UTVs, buses, boats and other water-based vessels, trains, bicycles, airplanes and other aerial vehicles (manned and unmanned), golf carts, and other vehicles. The battery packs can also be used in non-vehicle applications such as battery storage, uninterruptable power supplies and back-up power supplies. The battery pack test connector is configured to connect to a terminal on the battery pack to conduct the testing.

The battery pack test connector described herein can be configured to perform electrical testing, leak testing, or perform both electrical testing and leak testing. The ability to perform both electrical testing and leak testing using the same, single test connector eliminates the need for separate test connectors, one for electrical testing and one for leak testing.

The test connector described herein may also include a removable and replaceable cartridge that includes the electrical contacts for electrical connection with the electrical contacts of the battery pack terminal and/or that includes a vacuum/pressure leak test passageway together with a mechanical seal for conducting leak testing. When one or more parts of the test connector, such as the electrical contacts or the mechanical seal, become worn and need replacement, the cartridge may be removed from the test connector and replaced with a replacement cartridge. This helps to reduce replacement costs compared to conventional test connectors where the entire test connector is replaced when wear takes place.

A test connector with electrical contacts described herein may also have a life cycle of, for example, 20,000 cycles or more, or 50,000 cycles of more, or around 50,000-70,000 cycles. In contrast, conventional test connectors have a life cycle of around 7,000-10,000 cycles. In one embodiment, the electrical contacts can be provided with a coating to improve wear, protect against oxidation, improve corrosion resistance, and have low contact resistance (both physical and electronic).

In one embodiment, a battery pack test connector can include a connector body, electrical contacts on the connector body configured to electrically engage with terminal electrical contacts of a terminal of a battery pack, and a vacuum/pressure leak test passageway on the connector body. A mechanical seal on the connector body is configured to fluidically seal the connector body with the terminal to permit vacuum/pressure leak testing through the vacuum/pressure leak test passageway. In addition, a mechanical connector on the connector body detachably mechanically connects the connector body to the terminal.

In another embodiment, a battery pack test connector can include a connector body having a main body and a cartridge detachably connected to the main body. The cartridge includes a first end, a second end, and electrical contacts at the first end that are electrically engageable with terminal electrical contacts of a terminal of a battery pack. The electrical contacts extend to the second end and are detachably electrically engageable with electrical contacts on the main body.

In another embodiment, a replaceable cartridge for use with a battery pack test connector can include a first end, a second end, and electrical contacts at the first end that are detachably electrically engageable with terminal electrical contacts of a terminal of a battery pack. The electrical contacts extend to the second end and are detachably electrically engageable with electrical contacts on a main body of the battery pack test connector. The cartridge may also include a vacuum/pressure leak test passageway and a mechanical seal adjacent the first end that is configured to fluidically seal the replaceable cartridge with the terminal to permit vacuum/pressure leak testing through the vacuum/pressure leak test passageway. The mechanical seal is located on the cartridge to surround the electrical contacts at the first end and surround the vacuum/pressure leak test passageway.

In another embodiment, a method of testing a terminal of a battery pack includes connecting a battery pack test connector to terminal electrical contacts of the terminal of the battery pack. An electrical test on the terminal electrical contacts of the terminal is performed using the battery pack test connector. In addition, a vacuum/pressure leak test of the terminal is performed using the battery pack test connector. The electrical test may be performed prior to or after the vacuum/pressure leak test. In addition, the electrical test may be performed at the same time as, or temporally overlap with, conduction of the vacuum/pressure leak test.

### DRAWINGS

FIG. 1 is a schematic example of a battery pack with a terminal.

FIG. 2 is a perspective view of an embodiment of a battery pack test connector described herein configured for both electrical testing and leak testing.

FIG. 3 is a perspective view of another embodiment of a battery pack test connector described herein configured for electrical testing with no leak testing.

FIG. 4 is a perspective view of the battery pack test connector of FIG. 2 with the cartridge detached from the main body.

FIG. 5 is a longitudinal cross-sectional view of the battery pack test connector of FIG. 2.

FIG. 6 is another longitudinal cross-sectional view of the battery pack test connector of FIG. 2.

FIG. 7 is another longitudinal cross-sectional view of the battery pack test connector of FIG. 2.

FIG. 8 is a longitudinal cross-sectional view of the cartridge removed from the main body.

FIG. 9 is another longitudinal cross-sectional view of the cartridge.

FIG. 10 is a longitudinal cross-sectional view of the battery pack test connector of FIG. 2 relative to and disconnected from a battery pack terminal.

FIG. 11 is a longitudinal cross-sectional view of the battery pack test connector of FIG. 2 relative to and connected to the battery pack terminal.

FIG. 12 depicts a method of using a battery pack test connector described herein.

FIG. 13 depicts another method of using a battery pack test connector described herein.

### DETAILED DESCRIPTION

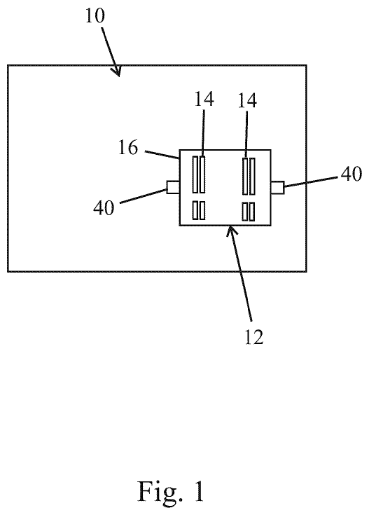

Referring to FIG. 1, a schematic example of a battery pack 10 with an electric terminal 12 is depicted. The terminal 12 is representative of electric terminals on battery packs used in electrically powered vehicles including but not limited to, automobiles or cars, trucks, motorcycles, ATVs and UTVs, buses, boats and other water-based vessels, trains, bicycles, airplanes and other aerial vehicles (manned and unmanned), golf carts, and other vehicles; as well as battery packs used in non-vehicle applications such as uninterruptable power supplies and back-up power supplies. The terminal 12 includes a plurality of electrical contacts 14 that during use can be electrically connected to in order to draw power from the battery pack 10 or to recharge the battery pack 10 or to electrically test the battery pack operation including but not limited to conductivity, resistance, power output, etc. The terminal 12 further includes a shield or wall 16 that projects from a bulkhead of the battery pack 10 and surrounds the contacts 14. Many configurations of the terminal 12 are possible and the specific configuration of the terminal 12 is not limiting as long as the battery pack test connector described herein can connect to the terminal 12 to perform the functions described herein.

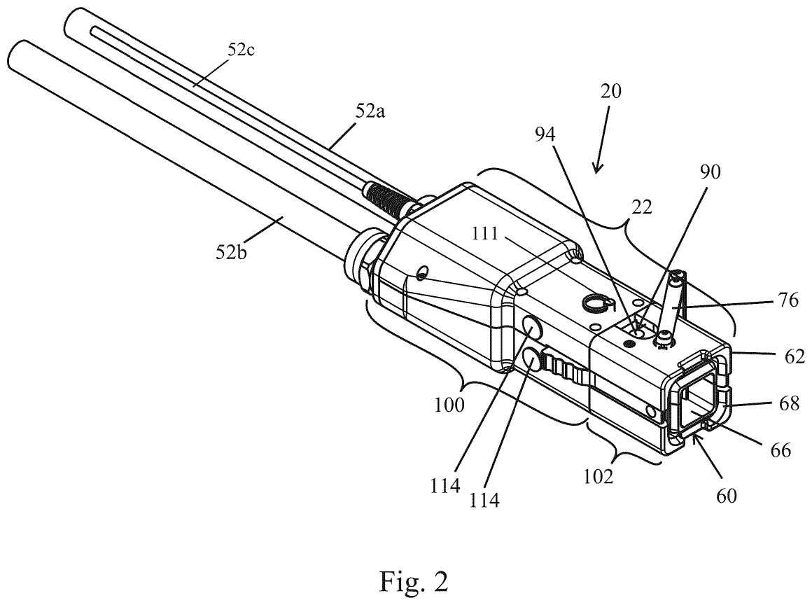

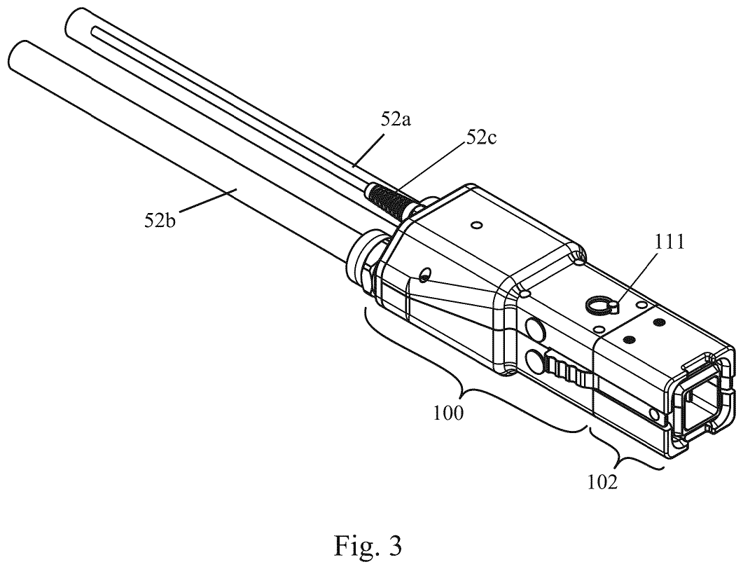

With reference to FIG. 2, an example of a battery pack test connector 20 is illustrated. In this example, the test connector 20 includes a connector body 22 that is configured to perform both electrical testing and leak testing (FIGS. 2 and 4-7). However, the connector body 22 can be configured for only electrical testing (FIG. 3) or only leak testing (not shown). When the connector body 22 is configured to perform both electrical testing and leak testing, the connector body 22 is configured to detachably mechanically connect to the terminal 12 and electrically engage with the electrical contacts 14 of the terminal 12 of the battery pack 10 of FIG. 1 for electrical testing. In addition, the connector body 22 is configured to fluidically seal with the terminal 12 in order to perform a vacuum/pressure leak test.

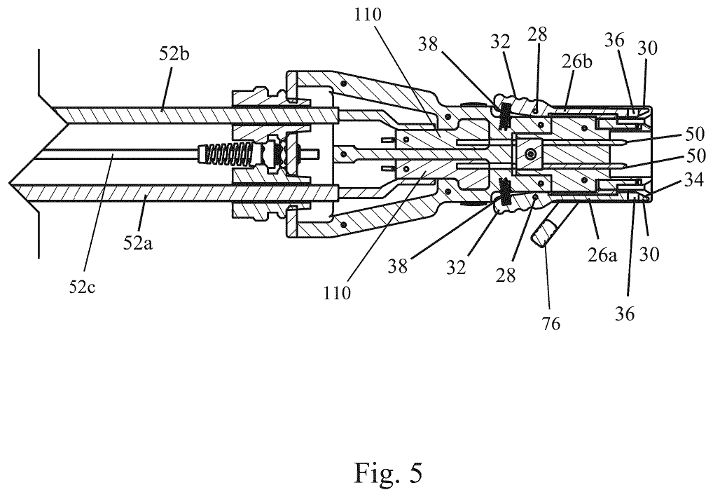

For example, referring to FIGS. 2 and 4-7, the connector body 22 has a mechanical connector 24 that includes a pair of connector arms 26a, 26b disposed opposite one another on opposite sides of the connector body 22 and that are pivotally attached to the connector body 22 via pivot pins 28 (best seen in FIG. 5). Each connector arm 26a, 26b includes a first end 30 and a second end 32. The first end 30 is disposed adjacent to the end of the connector body 22 that connects to the terminal. The first end 30 includes an angled ramp surface 34 and a through hole 36. The second end 32 is configured to project upward from the connector body 22, and a biasing spring 38 is engaged with the second end 32 to bias the second end 32 of the respective arm 26a, 26b upward to a home position shown FIG. 5.

Referring to FIGS. 1-2, 4-5 and 10-11, in use, as the connector body 22 is advanced toward the terminal, the ramp surfaces 34 of the first ends 30 of the connector arms 26a, 26b engage pins 40 on the wall 16 of the terminal 12 (see FIGS. 1 and 10-11). The pins 40 force the arms 26a, 26b to pivot upward against the biasing force of the springs 38. As the connector body 22 continues to advance, the pins 40 reach the holes 36 and the bias springs 38 then return the arms 26a, 26b back to the home position with the pins 40 in the holes 36 thereby releasably locking the connector body 22 to the terminal 12. In other embodiments, instead of the pins 40, ledges or other features can be provided on the terminal 12 for connection to/gripping by the connector arms 26a, 26b. The connector body 22 can be released from the terminal 12 by manually pressing down on the second ends 32 of the connector arms 26a, 26b which pivots the first ends 30 upward to release the pins 40 from the holes 36 and thereby allowing release of the connector body 22 from the terminal 12.

Referring to FIGS. 1, 5-6 and 10-11, the connector body 22 further includes electrical contacts 50 that are configured to electrically engage with the electrical contacts 14 of the terminal 12 when the connector body 22 is connected to the terminal 12. In the illustrated example, the electrical contacts 50 are recessed within the connector body 22 so that the ends of the electrical contacts 50 do not extend past the end of the connector body 22. The electrical contacts 50 are electrically connected to electrical cables 52a, 52b that direct electrical energy into and/or from the connector body 22. The cables 52a, 52b may be high voltage or low voltage or anywhere in between. A third cable 52c can be provided which may be configured for a 4-wire Kelvin resistance measurement. The number and configuration of the cables 52a-c may vary and may be used for power and/or data. The illustrated example depicts two of the electrical contacts 50. However, the connector body 22 can include a larger or smaller number of electrical contacts. For example, in an embodiment, the number of electrical contacts can range anywhere from 1 to 100. In another embodiment, there may be more than 100 of the electrical contacts. In addition, the shape of the connector body 22 depicted in the drawings may be characterized as being generally rectangular. However, other shapes of the connector body 22 are possible including generally round/cylindrical, generally hexagonal, and others.

In an embodiment, the electrical contacts 50 may be coated with a coating to improve wear, protect against oxidation, improve corrosion resistance, and have low contact resistance (both physical and electronic). The coating can be any coating that can enhance one or more of these properties of the electrical contacts 50. In an embodiment, the coating on the electrical contacts should be sufficient to provide the electrical contacts with a life cycle of, for example, about 20,000 cycles or more, or about 50,000 cycles of more, or between 50,000-70,000 cycles, or more than 70,000 cycles. In an embodiment, the coating can be electroless nickel, electroless palladium, immersion gold (ENEPIG) plating. However, other coatings are possible.

Referring to FIGS. 2 and 4-9, the connector body 22 is also configured to perform leak testing and includes a mechanical seal 60 on the connector body 22 that is positioned and configured to fluidically seal the connector body 22 with the terminal 12 to permit vacuum/pressure leak testing. The mechanical seal 60 is located adjacent to the first end 62 of the connector body 22 and surrounds the electrical contacts 50 and a vacuum/pressure leak test passage described further below. In the illustrated example, the mechanical seal 60 is within the interior of the connector body 22. The connector body 22 includes a fixed internal body 64 with a sleeve 66 that surrounds the contacts 50. The sleeve 66 includes a radial shoulder 68. The shoulder 68 may be circumferentially continuous or circumferentially discontinuous. The connector body 22 further includes a movable body 70. The movable body 70 surrounds a portion of the internal body 64 and a portion of the sleeve 66. The movable body 70 includes a sleeve 72 that extends toward the shoulder 68. An elastomeric seal 74 is disposed between the end of the sleeve 72 and the shoulder 68.

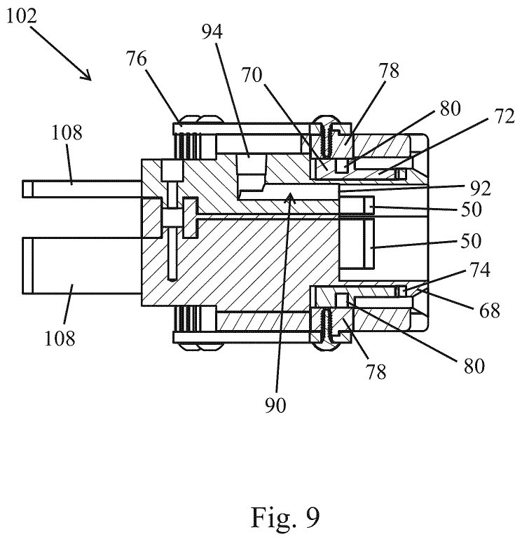

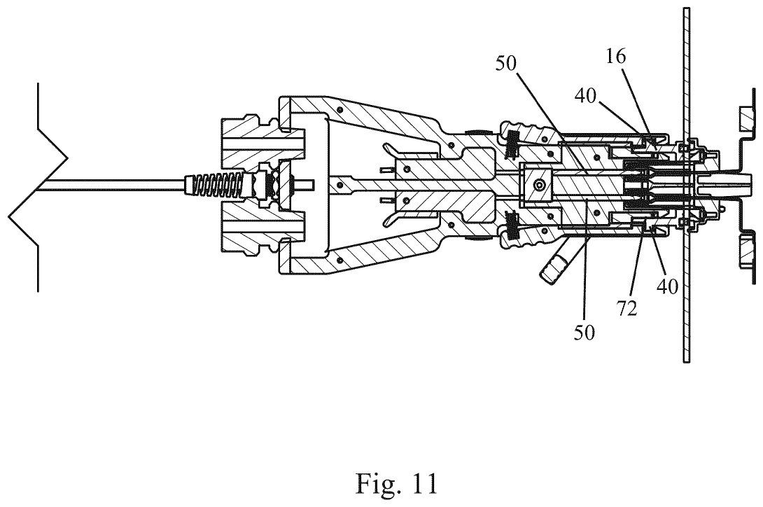

A seal actuating handle 76 is disposed on the connector body 22 and is rotatable relative to the connector body 22. Referring to FIG. 9, the actuating handle 76 is connected to cams 78 with offset pins 80 that are fixed to the movable body 70. As the handle 76 is rotated forward from the position shown in FIGS. 2, 4-6 and 8, the cams 78 rotate which cause the offset pins 80 to force the movable body 70 forward. As the movable body 70 moves forward, the sleeve 72 is actuated toward the shoulder 68 squeezing the seal 74 between the end of the sleeve 72 and the shoulder 68. This causes the seal 74 to extrude radially outward. When the connector body 22 is connected to the terminal 12, the shield 16 of the terminal 12 is disposed radially outward of the sleeve 72 as seen in FIG. 11. When the seal 74 is extruded radially outward, it seals against the inner surface of the shield 16 and forms a fluid-tight seal between the connector body 22 and the terminal 12.

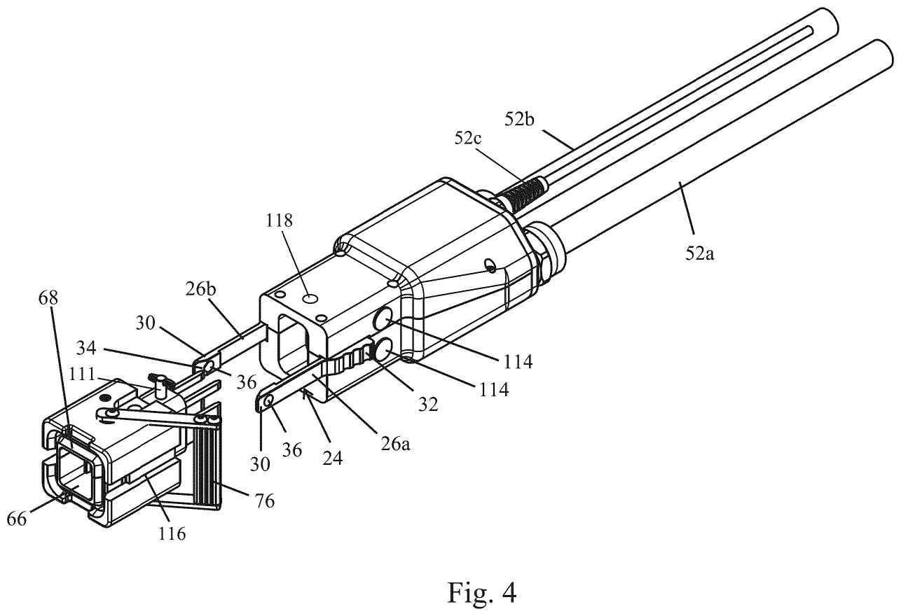

FIGS. 2 and 4 depict the sleeve 66 and the radial shoulder 68 as being generally square. The movable body 70 and the sleeve 72 are also generally square. As a result, the seal 74 is also generally square. However, other shapes of the components and the seal 74 are possible including rectangular, circular, oval, triangular, and other shapes.

To be able to perform leak testing, the connector body 22 also includes a vacuum/pressure leak test passageway 90. The passageway 90 is located on the connector body 22 at any suitable location for performing vacuum/pressure leak testing. For example, referring to FIGS. 2, 6-7, and 9, the passageway 90 can include a first port 92 that opens into the interior space defined by the sleeve 66 and located near the electrical contacts 50. The passageway 90 can also include a second port 94 that opens to the exterior of the connector body 22. A fluid passage extending through the internal body 64 fluidly connects the ports 92, 94. The port 94 can be fluidly connected to by a vacuum/pressure source (not shown) for conducting a vacuum/pressure leak test by, when the test connector 20 is sealed with the terminal 12, pulling a vacuum, or introducing pressure, to determine if the terminal 12 leaks. In an embodiment, the passageway 90 could be used as a fill passageway for testing, for example pressurizing with helium through the passageway 90 for testing the terminal 12.

The use of the electrical contacts 50 is optional and the connector body 22 could be configured for just vacuum/pressure leak testing with just the mechanical seal 60 and the vacuum/pressure leak test passageway 90 described above. In another embodiment, referring to FIG. 3, the connector body 22 can be configured for just electrical testing and provided with the electrical contacts 50. The connector in FIG. 3 does not include the leak test passageway 90, the ports 92, 94, and the mechanical seal 60. However, in an embodiment, the connector body 22 can include the electrical contacts 50 even if the connector body 22 is only used for vacuum/pressure leak testing, and the connector body 22 can include the vacuum/pressure leak test passageway 90 even if the connector body 22 is only used for electrical testing.

In an embodiment, referring to FIGS. 2 and 3, the connector body 22 may be formed by a main body 100 and a cartridge 102 that is detachably connected to the main body 100. The cartridge 102 is removable and replaceable with a new cartridge 102 which is useful when certain components of the connector body 22 wear and need replacement. Rather than replacing the entire connector body 22 when wear occurs, only the cartridge 102 is replaced.

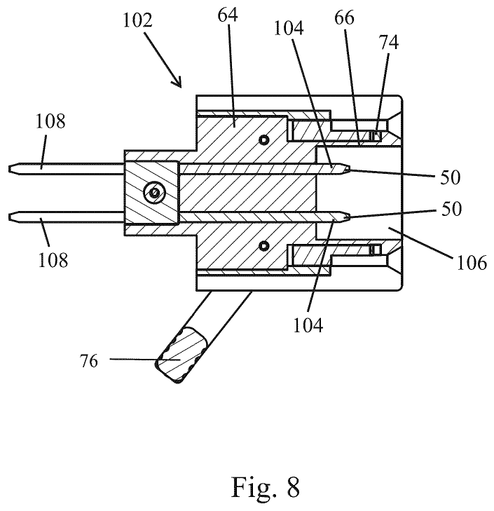

In the illustrated example, as best seen in FIGS. 8 and 9, the cartridge 102 can be configured to include the electrical contacts 50, the mechanical seal 74, and the vacuum/pressure leak test passageway 90. If any one or more of these items wear or need replacement or the user wishes to alter the performance characteristics (electrical and/or fluid), the cartridge 102 can be disconnected from the main body 100 and replaced with a different cartridge 102. In an embodiment, the cartridge 102 can include just the electrical contacts 50 and not include the mechanical seal 74 or the vacuum/pressure leak test passageway 90. In another embodiment, the cartridge 102 can include just the mechanical seal 74 and the vacuum/pressure leak test passageway 90, and not include the electrical contacts 50. In addition, in another embodiment, rather than replacing the cartridge 102, it is possible that the seal 74 can be replaced when worn rather than replacing the entire cartridge 102. Further, in an embodiment of the connector body 22 without the replaceable cartridge 102, it is possible that the seal 74 can be replaced when worn.

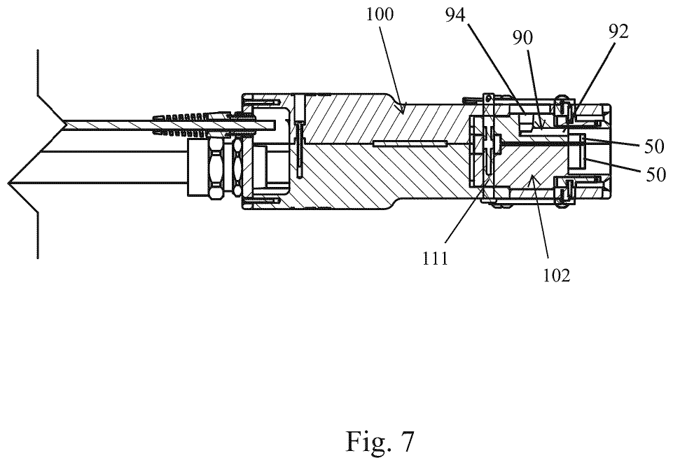

Referring to FIGS. 2, 4 and 7, the cartridge 102 is primarily secured to the main body 100 via one or more fasteners 111. In this example, there is a single fastener 111 which can be, for example, a pin such as a clevis pin, that extends laterally through the main body 100 and the internal body 64 of the connector body 22 as best seen in FIG. 7. FIG. 4 depicts the main body 100 as including a hole 118 that the pin will extend through as best seen in FIG. 2. The use of a single pin such as a clevis pin provides fast and easy change of the cartridge 102.

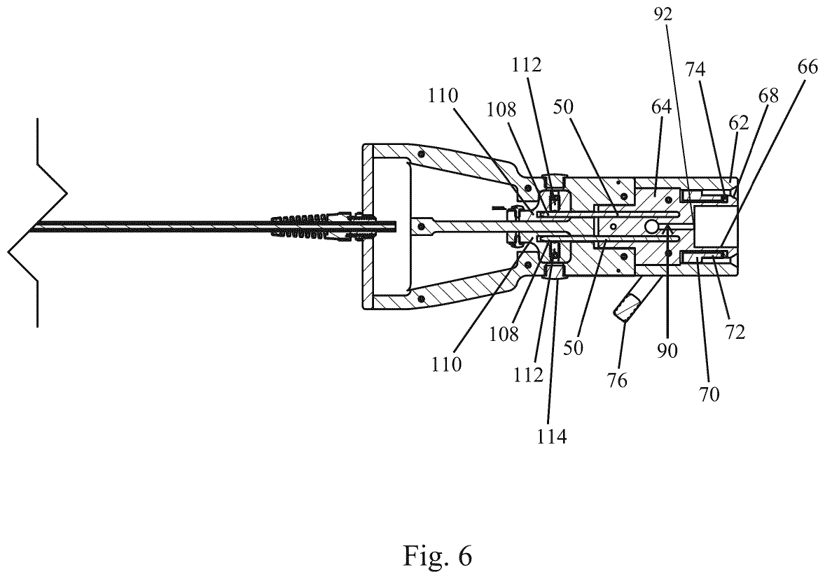

Referring to FIGS. 6 and 8-10, the electrical contacts 50 have first ends 104 that extend into the interior space 106 defined by the sleeve 66. The contacts 50 extend through the internal body 64 with second ends 108 extending from and beyond the internal body 64 (FIGS. 8-9). When the cartridge 102 is connected to the main body 100, the second ends 108 slide into electrical contacts 110 on the main body 100 as best seen in FIG. 6. The electrical contacts 110 are electrically connected to the cables 52a, 52b. One or more mechanical fasteners 112, such as set screws, one or more pins or like, secure the second ends 108 to the electrical contacts 110 and also help fasten the cartridge 102 to the main body 100. The fasteners 112 may be disposed in holes that are covered by one or more removable caps 114, which may be plastic, and are removed to access the fasteners 112. In an embodiment, the electrical contacts 110 may have a configuration like the contacts 14 where the ends 108 of the contacts 50 slide into, electrically engage with, and are mechanically clamped by the electrical contacts 110. In such an embodiment, the use of the fasteners 112 is optional if the clamping of the ends 108 by the electrical contacts 110 is considered sufficient to achieve adequate electrical connection and sufficient to help fasten the cartridge 102 to the main body 100.

As best seen in FIG. 4, the connector arms 26a, 26b are disposed on the main body 100 and portions of the arms 26a, 26b project forwardly from the main body 100. The arms 26a, 26b slide through channels 116 formed in the outside surface of the cartridge 102, with the first ends 30 of the arms 26a, 26b disposed adjacent to the end 62.

The connector body 22, including the main body 100 and/or the cartridge 102, can be made of materials suitable for use with the voltages expected during use of the test connector 20. In an embodiment, the main body 100 and the cartridge 102 (except for the electrical contacts 50, the electrical contacts 110 and the fasteners 112) can be made of an electrically non-conductive material, for example a plastic material.

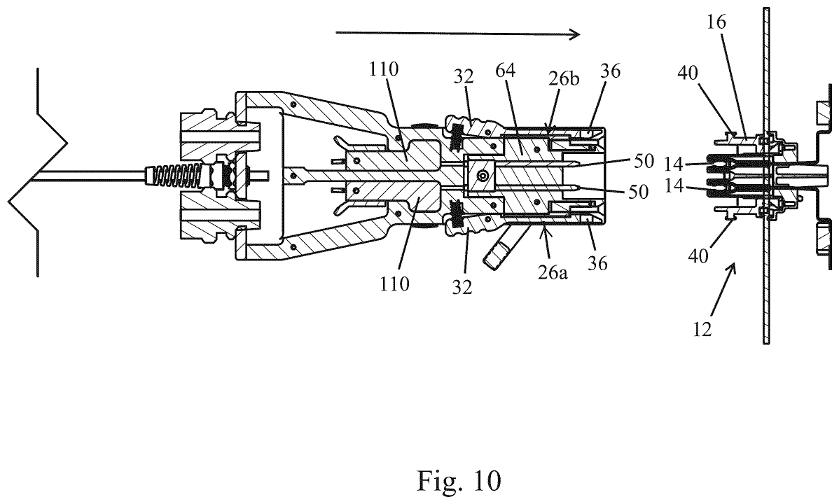

An example operation of the test connector 20 is as follows. Referring to FIGS. 10 and 11, with the cartridge 102 connected to the main body 100, the connector body 22 is brought toward the terminal 12. The connector body 22 is installed onto the terminal 12 by directing the connector body 22 around the shield 16 with the shield 16 surrounding the sleeve 72, and with the contacts 50 sliding into the contacts 14. As the connector body 22 advances, the ramp surface 34 on the connector arms 26a, 26b engage the pins 40 deflecting the arms 26a, 26b outward until arms 26a, 26b snap into position with the pins 40 in the holes 36. The connector body 22 is now mechanically and electrically connected to the terminal 12. If vacuum/pressure leak testing is desired, the seal actuating handle 76 is rotated forwarded which drives the movable body 70 forward causing the seal 74 to extrude outward into sealing engagement with the interior surface of the shield 16. Vacuum/pressure leak testing can then take place via the test passageway 90.

The connector body 22 and the terminal 12 can be disconnected as follows. If the connector body 22 is sealed with the terminal 12, the seal actuating handle 76 is rotated in reverse which drives the movable body 70 rearward which removes pressure on the seal 74 and disengages the sealing engagement with the terminal 12. The user then manually presses the ends 32 of the arms 26a, 26b inward which deflects the ends 30 upward so that the pins 40 are removed from the holes 36 releasing the mechanical connection. With the user continuing to press the ends 32 inward, the user can then pull the connector body 22 away from the terminal 12 to disengage the contacts 50 and the contacts 14.

If the connector body 22 is configured with the main body 100 and the cartridge 102, and one or more parts of the cartridge 102 are worn and needs replacement and/or the user wants to change performance characteristics of the cartridge 102, the user can remove the fastener(s) 112 and disconnect the cartridge 102 from the main body 100. A new cartridge 102 can then be connected to the main body 100 and secured to the main body 100 using the fastener(s) 112.

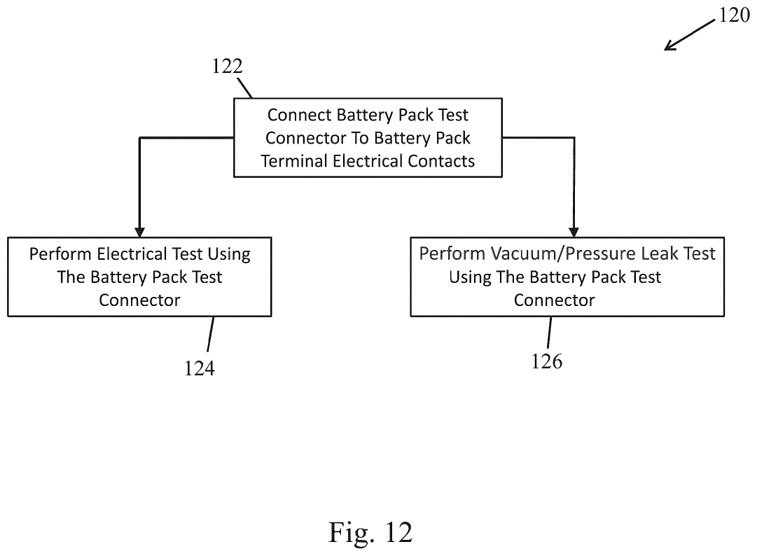

FIG. 12 illustrates an example method of use 120 of the test connector 20. The test connector 20 may or may not include the main body 100 and the cartridge 102 described above. As used herein, the word “step” can include a single action that forms the step or multiple actions that form the step. In the method 120, in step 122 the test connector is connected to the terminal 12 of the battery pack as described above. Thereafter, depending upon the construction of the test connector 20 and the intent of the user, in step 124 the test connector 20 can be used to perform an electrical test. Alternatively or additionally, the test connector 20 can be used to perform a vacuum/pressure leak test in step 126. The steps 124, 126 can be performed in any order including performing the step 126 prior to performing the step 124. In an embodiment, the steps 124, 126 can be performed simultaneously.

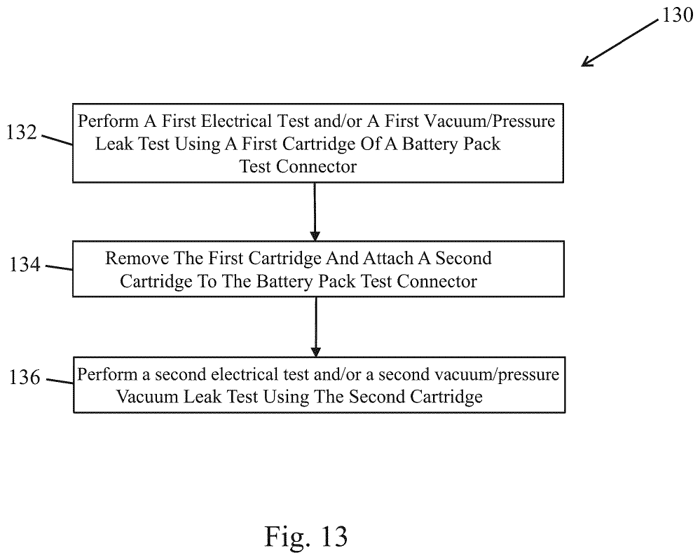

FIG. 13 illustrates another example method of use 130 of the test connector 20 assuming that the test connector 20 includes the main body 100 and the removable cartridge 102 described above. As used herein, the word “step” can include a single action that forms the step or multiple actions that form the step. In the method 130, the test connector is connected to the terminal 12 of the battery pack as described above. Thereafter, in step 132, a first electrical test and/or a first vacuum/pressure leak test is performed using a first cartridge 102 connected to the main body 100 of the test connector 20. Thereafter, in step 134, the test connector 20 is disconnected from the terminal, the first cartridge 102 is detached from the main body 100, and a second cartridge 102 is attached to the main body 100. Thereafter, the test connector is again connected to a terminal of a battery pack, and in step 136 a second electrical test and/or a second vacuum/pressure leak test is performed using the second cartridge 102 connected to the test connector 20. The test connector with the second cartridge can connect to the same battery pack connected to in step 132 or the test connector with the second cartridge can connect to a different battery pack.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A battery pack test connector comprising:
a connector body;
electrical contacts on the connector body configured to electrically engage with terminal electrical contacts of a terminal of a battery pack;
a vacuum/pressure leak test passageway on the connector body;
a mechanical seal on the connector body configured to fluidically seal the connector body with the terminal to permit vacuum/pressure leak testing through the vacuum/pressure leak test passageway;
a mechanical connector on the connector body configured to detachably mechanically connect the connector body to the terminal.

2. The battery pack test connector of claim 1, wherein the mechanical seal surrounds the electrical contacts and the vacuum/pressure leak test passageway.

3. The battery pack test connector of claim 1, wherein the connector body comprises a main body and a cartridge detachably connected to the main body; the cartridge includes:
the electrical contacts that are detachably electrically engageable with electrical contacts on the main body;
the vacuum/pressure leak test passageway; and
the mechanical seal.

4. The battery pack test connector of claim 3, wherein the mechanical connector is on the main body.

5. The battery pack test connector of claim 3, wherein the electrical contacts on the cartridge include a wear coating, and the cartridge has a life cycle of at least 20,000 cycles.

6. The battery pack test connector of claim 5, wherein the cartridge has a life cycle of at least 50,000 cycles.

7. A battery pack test connector comprising:
a connector body having a main body and a cartridge detachably connected to the main body;
the cartridge includes:
a first end, a second end, electrical contacts at the first end that are electrically engageable with terminal electrical contacts of a terminal of a battery pack, and the electrical contacts extend to the second end and are detachably electrically engageable with electrical contacts on the main body.

8. The battery pack test connector of claim 7, wherein the cartridge further includes a vacuum/pressure leak test passageway and a mechanical seal configured to fluidically seal the cartridge with the terminal to permit vacuum/pressure leak testing through the vacuum/pressure leak test passageway; and the mechanical seal surrounds the electrical contacts of the cartridge and the vacuum/pressure leak test passageway.

9. The battery pack test connector of claim 7, further comprising a mechanical connector on the main body that is configured to detachably mechanically connect to the terminal.

10. The battery pack test connector of claim 7, wherein the electrical contacts at the first end include a wear coating, and the cartridge has a life cycle of at least 20,000 cycles.

11. The battery pack test connector of claim 10, wherein the cartridge has a life cycle of at least 50,000 cycles.

12. A replaceable cartridge for use with a battery pack test connector, the replaceable cartridge comprising:
a first end, a second end, electrical contacts at the first end that are detachably electrically engageable with terminal electrical contacts of a terminal of a battery pack, and the electrical contacts extend to the second end and are detachably electrically engageable with electrical contacts on a main body of the battery pack test connector;
a vacuum/pressure leak test passageway and a mechanical seal adjacent the first end that is configured to fluidically seal the replaceable cartridge with the terminal to permit vacuum/pressure leak testing through the vacuum/pressure leak test passageway, and the mechanical seal surrounds the electrical contacts at the first end and surrounds the vacuum/pressure leak test passageway.

13. The replaceable cartridge of claim 12, wherein the electrical contacts at the first end include a wear coating, and the replaceable cartridge has a life cycle of at least 20,000 cycles.

14. The replaceable cartridge of claim 13, wherein the replaceable cartridge has a life cycle of at least 50,000 cycles.

15. A method of testing a terminal of a battery pack, comprising:
connecting a battery pack test connector to terminal electrical contacts of the terminal of the battery pack;
performing an electrical test on the terminal electrical contacts of the terminal using the battery pack test connector; and
performing a vacuum/pressure leak test of the terminal using the battery pack test connector.

16. The method of claim 15, wherein the battery pack test connector comprises a main body and a cartridge that is detachably connected to the main body; and comprising:
connecting a first cartridge to the main body and performing a first electrical test on terminal electrical contacts of a first terminal and a first vacuum/pressure leak test on the first terminal using the first cartridge connected to the main body;
detaching the first cartridge from the main body and connecting a second cartridge to the main body; and
performing a second electrical test on terminal electrical contacts of a second terminal and a second vacuum/pressure leak test on the second terminal using the second cartridge connected to the main body.
